(19) United States
(12) Patent Application Publication
(10) Pub. No.: US 2006/0006864 A1
(43) Pub. Date: Jan. 12, 2006

(54) Integrated magnetoresitive speed and direction sensor

(75) Inventors: Curtis B. Johnson, Freeport, IL (US); Gregory R. Furlong, Freeport, IL (US); Wayne A. Lamb, Freeport, IL (US); Wayne T. Kilian, Richardson, TX (US)

Correspondence Address: Kris T. Fredrick;Honeywell International, Inc., 101 Columbia Rd., P.O. Box 2245, Morristown, NJ, 07962, US

(73) Assignee: Honeywell International, Inc.

(21) Appl. No.: 10/940,091

(22) Filed: Sep. 14, 2004

Related U.S. Application Data
(60) Provisional application No. 60/586,769, filed on Jul. 8, 2004.

(51) Int. Cl. G01R 33/02

(52) U.S. Cl. 324/252

(57) ABSTRACT

An integrated circuit magnetoresistive speed and direction sensor generally utilizes an AMR bridge circuit thereby allowing for increased air gap performance as compared to conventional Hall-effect element based sensors. The AMR sensor is capable of sensing ring magnets or bar magnets magnetized with one or more magnet poles along the desired travel. The number of poles of the magnet should be optimized based upon the application design. In order to obtain speed and direction information, two bridge circuits can be placed within proximity (I.e., the exact location and shape of the bridge can be determined based upon the target and desired performance) of each other. The signals of the two bridge circuits can be compared on integrated electronics. The bridges are generally rotated 45 degrees to reduce and/or eliminate offsets, which provide the sensor with a large air gap performance.

### REFERENCE TO RELATED APPLICATION

This patent application claims priority under 35 U.S.C. § 119(e) to provisional patent application Ser. No. 60/586,769 entitled “Integrated Magnetoresistive Speed and Direction Sensor,” which was filed on Jul. 8, 2004, the disclosure of which is incorporated herein by reference.

### TECHNICAL FIELD

Embodiments are generally related to sensor methods and systems. Embodiments are also related to speed and direction sensors. Embodiments are additionally related to magnetoresistive sensing devices, including AMR sensing elements and integrated circuit implementations thereof. Embodiments are also related to AMR bridge circuits.

### BACKGROUND OF THE INVENTION

The use of electronics in the automotive and aerospace industries, especially in the area of electronic and electromechanical control systems has been and will continue to increase. For example, electronic engine, transmission, and steering controllers and in the aerospace field, electronic implement controllers all are becoming more common and more complex.

Typically, the controller is supplied with data from a number of sensors. As a result of the increasing complexity of such systems, the information or data that the sensors are required to provide also increases in complexity, for example, the amount of information conveyed, the accuracy of the data, the dependability of the data, and the speed at which it is acquired. Today's sensors typically must increase each of these parameters while minimizing overall costs.

Electronic controllers, for example, are provided on modern vehicles to monitor the operation of the vehicle and provide information to the engine, transmission and other systems to control the functions thereof. One parameter which is monitored in several systems of the vehicles is the speed of rotating components. Some rotating components are provided in the transmission, driveline, and wheels.

Most conventional systems detect the speed of these components, but often do not provide directional information. In such systems, a sensor detects the rotation of a rotating component. Typically, a rotor is provided with a plurality of evenly spaced teeth, fixed to a rotating shaft. The rotor rotates with the shaft and a pickup sensor is placed in a position adjacent the rotor to sense the teeth as the rotor moves beneath the sensor. A controller can be provided to receive a signal from the sensor. By counting the teeth and measuring time, the controller may calculate the speed of the shaft.

Additional sensors are required in most conventional systems to determine the direction of rotation of the component. In such a system, two sensors can be placed in a particular spatial relationship with the teeth of the rotor. The sensors determine relative times at which an edge is detected. Thereafter, the controller may determine the direction of rotation. The additional sensor adds cost to the system and reduces reliability.

Thus, a continuing need exists for accurately and efficiently sensing the speed and direction of rotating and linear targets, particularly in the automotive and aerospace industries. One of the problems with conventional systems is that the gap performance must be large enough to accommodate mechanical tolerance and variations of the overall systems. Conventional systems typically lack such a large gap performance. That is, the distance between the sensor and target may vary given the tolerance of the target travel or rotation (i.e., axial run out or mis-position). Thus, air gap performance is a critical factor in speed and direction sensing. It is believed that the embodiments disclosed herein solve air gap performance difficulties.

### BRIEF SUMMARY OF THE INVENTION

The following summary of the invention is provided to facilitate an understanding of some of the innovative features unique to the present invention and is not intended to be a full description. A full appreciation of the various aspects of the invention can be gained by taking the entire specification, claims, drawings, and abstract as a whole.

It is, therefore, one aspect of the present invention to provide for improved sensor methods and systems.

It is another aspect of the present invention to provide for improved speed and direction sensing methods and systems.

It is a further aspect of the present invention to provide for improved speed and direction sensors that incorporate magnetoresistive sensing elements.

The aforementioned aspects of the invention and other objectives and advantages can now be achieved as described herein. An integrated magnetoresistive speed and direction sensor, including methods and systems thereof, are disclosed herein. The sensor illustrated and described herein generally utilizes an AMR (Anisotropic Magnetoresistive) bridge circuit. Using this technology allows for increased air gap performance as compared to conventional Hall-effect element based sensors. The AMR sensor disclosed herein is capable of sensing ring magnets or bar magnets magnetized with one or more magnet poles along the desired travel. The number of poles of the magnet should be optimized based upon the application design. The AMR bridge design of the AMR sensor disclosed herein produces minimal offsets, which results in optimal performance thereof.

In order to obtain speed and direction information, two bridge circuits can be placed within proximity (i.e., the exact location and shape of the bridge can be determined based upon the target and desired performance) of each other. The signals of the two bridge circuits can be compared on the integrated electronics, which are co-located on the silicon thereof. The bridges are generally rotated 45 degrees to reduce and/or eliminate offsets, which provide the sensor with a large air gap performance.

### BRIEF DESCRIPTION OF THE DRAWINGS

The accompanying figures, in which like reference numerals refer to identical or functionally-similar elements throughout the separate views and which are incorporated in and form a part of the specification, further illustrate the present invention and, together with the detailed description of the invention, serve to explain the principles of the present invention.

FIG. 1 illustrates a block diagram of bond pad locations, an interface diagram and a graph representing supply current versus temperature, in accordance with one embodiment of the present invention;

FIG. 2 illustrates a timing diagram, in accordance with one embodiment of the present invention;

FIG. 3 illustrates a power-up diagram, in accordance with one embodiment of the present invention;

FIG. 4 illustrates a pictorial diagram of an MR bridge, along with MR bridge dimensions, in accordance with one embodiment of the present invention;

FIG. 5 illustrates a block diagram of a ring magnet, an air gap and an 8-pin package, in accordance with one embodiment of the present invention;

FIG. 6 illustrates a ring magnet and example ring magnet dimensions, in accordance with one embodiment of the present invention; and

FIG. 7 illustrates a system comprising an integrated circuit including two bridge circuits (or bridges) and runners positioned at 45 degrees, in accordance with a preferred embodiment of the present invention.

### DETAILED DESCRIPTION OF THE INVENTION

The particular values and configurations discussed in these non-limiting examples can be varied and are cited merely to illustrate at least one embodiment of the present invention and are not intended to limit the scope of the invention.

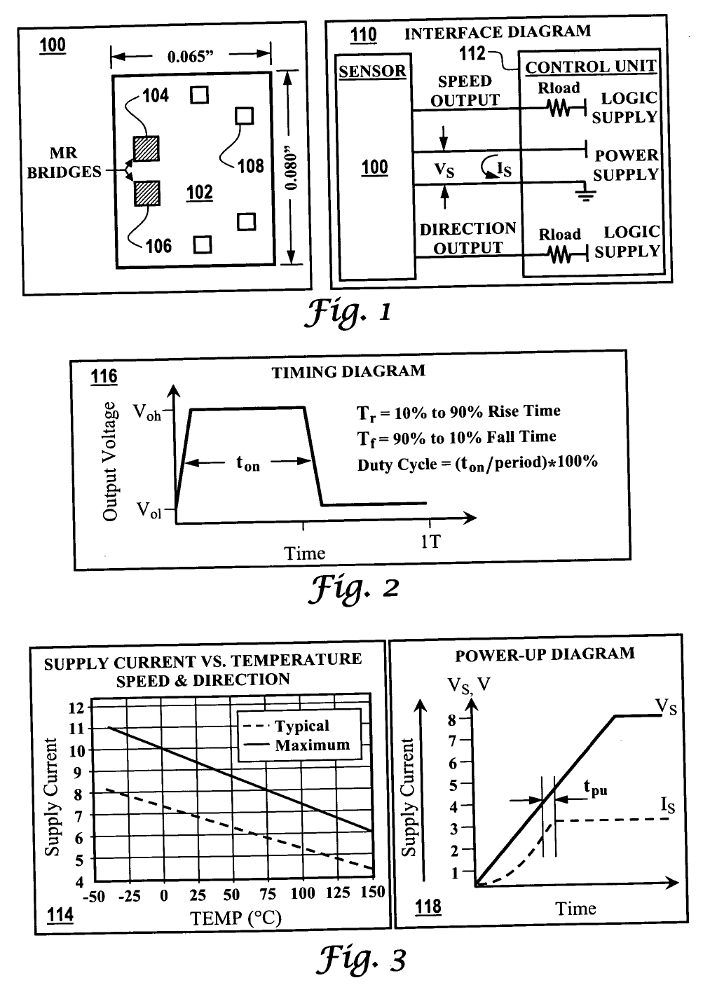

FIG. 1 illustrates a block diagram of bond pad locations, an interface diagram 110 a graph 114 representing supply current versus temperature, in accordance with one embodiment of the present invention. FIG. 2 illustrates a timing diagram 116, in accordance with one embodiment of the present invention. FIG. 3 illustrates a power-up diagram 118, in accordance with one embodiment of the present invention. FIGS. 1-2 are generally related to one another in the sense that graph 114, timing diagram 116 and power-up diagram 118 provide data indicative of the performance of sensor 100 depicted in FIG. 1. In general, sensor 100 includes at least two MR bridges 104 and 106. Note that as utilized herein, the term “bridge” can be utilized interchangeably with the term “bridge circuit” to refer to the same component. An approximate bond location 108 is depicted in FIG. 1.

Sensor 100 generally functions as a ring magnet speed and direction (RM S&D) sensor that can detect both the speed and direction of a ring magnet using anisotropic magnetoresistive (AMR) technology. The RM S&D IC generally comprises two output pins to provide speed and direction information. The standard configuration is a speed pin and direction pin. The frequency of the output signal on the speed pin is proportional to the rotational speed of the ring magnet. The digital output state of the direction pin indicates the direction of rotation of the ring magnet. Direction of the ring magnet is determined from the phase difference between two spacially separated AMR bridges 104 and 106 configured upon an integrated circuit (IC) 102.

The RM S&D sensor 100 can be implemented, for example, an Integrated Circuit housed within an 8-pin SOIC package. The Integrated Circuit can be implemented in a bipolar technology containing thin film AMR sensors. The RM S&D IC sensor 100 is well suited for rotational speed detection applications of ring magnet applications such as transmission systems, wheel speed systems, steering systems, or “Smart” door latch systems.

The AMR based sensor 100 can provide the following advantages over mechanical or other magnetic position sensing alternatives: Low cost, high sensitivity, fast response, small size, and reliability. A fully integrated circuit enables minimum cost and highest reliability by combining the AMR sensors with signal conditioning and output circuitry. Due to sensitivity to low magnetic fields, such sensors generally possess working air gaps, which allow the user to solve a variety of problems in custom applications.

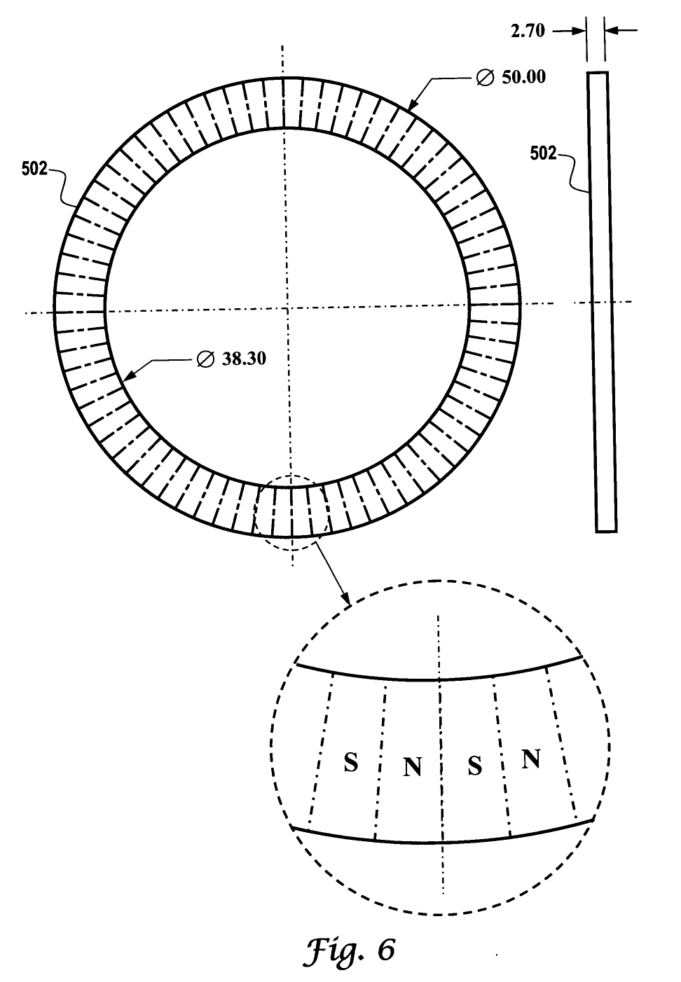

The RM S&D sensor 100 can be implemented as an 8-pin SOIC package, with 2 connections for Supply and Ground and 2 connections for the output, one for the speed and one for the direction signal. These will be open collector type outputs. The IC design of sensor 100 also offers the possibility of providing two speed outputs but external signal processing would be required to determine direction. This option can be achieved through different wafer masks. The sensor 100 can also provide a periodic square wave, where each period corresponds to one pole of a ring magnet, such as, for example ring magnet 502 disclosed in FIGS. 5 and 6 herein.

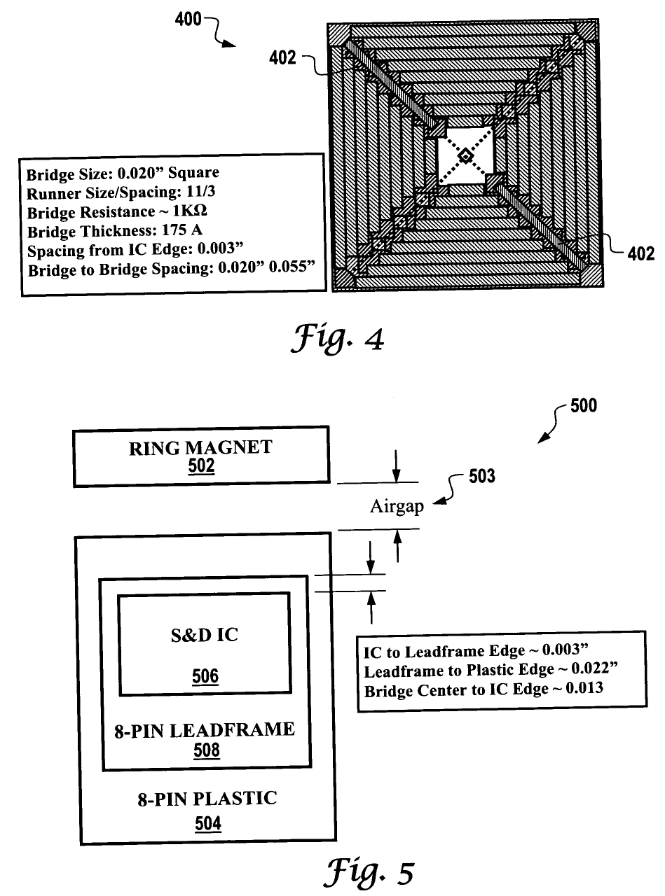

FIG. 4 illustrates a pictorial diagram of an MR bridge 400, along with suggested MR bridge dimensions, in accordance with one embodiment of the present invention. Runners 402 are also disclosed in FIG. 4. Such runners 402 can be positioned at 45 degrees. FIG. 5 illustrates a block diagram of a system 500 that includes a ring magnet 502, an air gap 503 and an 8-pin package 504, in accordance with one embodiment of the present invention. The 8-pin package 504 may be configured as a plastic package that includes an 8-pin lead frame and S&D IC 506, which is analogous to sensor 100 of FIG. 1. Thus, sensor 100 of FIG. 1 can be implemented in place of S&D IC 506, depending upon design considerations. FIG. 6 illustrates a ring magnet 502 and example ring magnet dimensions, in accordance with one embodiment of the present invention. It can be appreciated that all of the dimensions illustrated herein are merely suggested or preferred dimensions and that such dimensions may be large or smaller, depending upon design and implementation considerations. Such dimensions are therefore not considered limiting features of the invention disclosed herein and/or embodiments thereof.

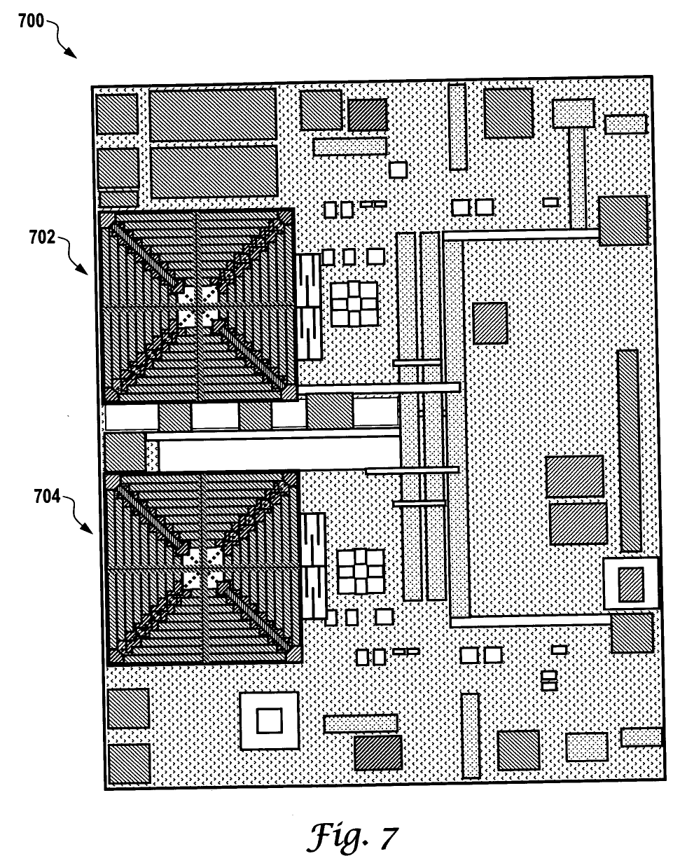

FIG. 7 illustrates a system 700 comprising an integrated circuit including two bridge circuits or bridges 702 and 704, and runners positioned at 45 degrees, in accordance with a preferred embodiment of the present invention. Each bridge 702 and 704 depicted in FIG. 7 is analogous or similar to MR Bridge 400 illustrated in FIG. 4 and the MR bridges 104 and 106 depicted in FIG. 1.

The embodiments disclosed herein generally are directed toward a sensor IC, such as system 700, which can meet the speed and direction sensing requirements for wheel speed sensors, transmission sensors, and universal latch systems. An IC such as system 700 can utilize two spacially separated MR bridges such as bridges 702 and 704 to determine speed and direction of rotation. The IC can be placed in the 8-pin SOIC surface mount package. This is what makes this device unique from other MR speed and direction sensors. The resulting sensing device can be implemented as a four wire device with supply, ground, and two outputs. The outputs are capable of providing two speed outputs or a speed and direction output. This effort has the potential to be used in the universal latch system as well as other possible applications in transmissions or wheel speed.

The speed and direction sensor disclosed herein can be applied to a number of systems, such as, for example, automotive transmission systems and automotive wheel speed systems. Other applications include automotive steering systems and “smart” automotive door latch systems. Additional applications include general rotational speed information gathering devices.

The embodiments and examples set forth herein are presented to best explain the present invention and its practical application and to thereby enable those skilled in the art to make and utilize the invention. Those skilled in the art, however, will recognize that the foregoing description and examples have been presented for the purpose of illustration and example only. Other variations and modifications of the present invention will be apparent to those of skill in the art, and it is the intent of the appended claims that such variations and modifications be covered.

The description as set forth is not intended to be exhaustive or to limit the scope of the invention. Many modifications and variations are possible in light of the above teaching without departing from the scope of the following claims. It is contemplated that the use of the present invention can involve components having different characteristics. It is intended that the scope of the present invention be defined by the claims appended hereto, giving full cognizance to equivalents in all respects.

1. A sensor system, comprising:
a first magnetoresistive bridge circuit placed in proximity to and spatially separated from a second magnetoresistive bridge circuit, wherein said first and second magnetoresistive bridge circuits are located on an integrated circuit; and
a magnetic target magnetized with a plurality of magnet poles along a desired path of travel, wherein said first and second magnetoresistive bridge circuits are located in proximity to said magnetic target, such that said first magnetoresistive bridge circuit generates a first signal and said second magnetoresistive bridge circuit generates a second signal, wherein said first and second signals are compared to one another and utilized to determine a speed and direction of said magnetic target and wherein said first and second magnetoresistive bridge circuits provide a magnetic sensitiviy that is approximately constant over an operating temperature thereof.

2. The system of claim 1 wherein said first and second magnetoresistive bridge circuits are located on said integrated circuit wherein said integrated circuit provides a speed pin and a direction pin, such that a frequency of an output and a digital output state of said direction pin indicates a direction of rotation of said ring magnet, wherein said direction of said ring magnet is determined from a phase difference between said first and second magnetoresistive bridge circuits.

3. (canceled)

4. The system of claim 1 further comprising a four terminal device comprising said first and second magnetoresistive bridge circuits, wherein said four terminal device comprises a power connection, a ground connection and first and second outputs, wherein said first and second outputs respectively provide speed and direction data, which provides data Indicative of said speed and direction of said magnetic target.

5. The system of claim 4 wherein said first output provides speed data in a form of a square wave signal with each period thereof corresponding to one pole of said magnetic target.

6. The system of claim 5 wherein said second output provides direction data in a digital state, which indicates a rotational direction of said magnetic target.

7. (canceled)

8. The system of claim 1 wherein said magnetic target comprises a ring magnet.

9. (canceled)

10. A sensor system, comprising:
a first bridge circuit placed in proximity to and spatially separated from a second bridge circuit, wherein said first and second bridge circuits are located on an integrated circuit (IC), and wherein said first bridge circuit comprises a magnetoresistive (MR) circuit and wherein said second bridge circuit comprises a magnetoresistive (MR) circuit;
a magnetic target magnetized with a plurality of magnet poles along a desired path of travel, wherein said first and second bridge circuits are located in proximity to said magnetic target, such that said first bridge circuit generates a first signal and said second bridge circuit generates a second signal, wherein said first and second signals are compared to one another and utilized to determine a speed and direction of said magnetic target;
wherein said integrated circuit comprises a four terminal device comprising said first and second bridge circuits, wherein said four terminal device comprises a power connection, a ground connection and first and second outputs, wherein said first and second outputs respectively provide speed and direction data, which provides data indicative of said speed and direction of said magnetic target; and
wherein said first output provides speed data in a form of a square wave signal with each period thereof corresponding to one pole of said magnetic target and wherein said second output provides direction data in a digital state, which indicates a rotational direction of said magnetic target and wherein said first and second MR bridge circuits provide a magnetic sensitivity that is approximately constant over an operating temperature range thereof.

11. (canceled)

12. (canceled)

13. (canceled)

14. A sensor method, comprising the steps of:
locating a first magnetoresistive bridge circuit placed in proximity to and spatially separated from a second magnetoresistive bridge circuit; and
providing a magnetic target magnetized with a plurality of magnet poles along a desired path of travel, wherein said first and second magnetoresistive bridge circuits are located in proximity to said magnetic target, such that said first magnetoresistive bridge circuit generates a first signal and said second magnetoresistive bridge circuit generates a second signal, wherein said first and second signals are compared to one another and utilized to determine a speed and direction of said magnetic target wherein said first and second magnetoresistive bridge circuits provide a magnetic sensitivity that is approximately constant over an operating temperature thereof.

15. The method of claim 14 further comprising the step of configuring said first and second bridge circuits on an integrated circuit (IC).

16. (canceled)

17. The method of claim 14 further comprising the step of:
providing a four terminal device comprising said first and second bridge circuits, wherein said four terminal device comprises a power connection, a ground connection and first and second outputs, wherein said first and second outputs respectively provide speed and direction data, which provides data Indicative of said speed and direction of said magnetic target.

18. The method of claim 17 further comprising the steps of:
generating speed data from said first output in a form of a square wave signal with each period thereof corresponding to one pole of said magnetic target;
generating direction data In a digital state from said second output to provide an indication of a rotational direction of said magnetic target; and
wherein said first and second bridge circuits provide a magnetic sensitivity that is approximately constant over an operating temperature range thereof.

19. The method of claim 18 further comprising the step of configuring said magnetic target to comprise a ring magnet.

20. The method of claim 18 further comprising the step of configuring said magnetic target to comprise a bar magnet.
